(19) United States
(12) Patent Application Publication
(10) Pub. No.: US 2008/0185669 A1
(43) Pub. Date: Aug. 7, 2008

(54) Silicon Microphone

(75) Inventors: Kitt-Wai Kok, Singapore (SG); Kok Meng Ong, Singapore (SG); Kathirgamasundaram Sooriakumar, Singapore (SG); Bryan Keith Patmon, Singapore (SG)

Correspondence Address: OHLANDT, GREELEY, RUGGIERO & PERLE, LLP, ONE LANDMARK SQUARE, 10TH FLOOR, STAMFORD, CT, 06901, US

(73) Assignee: SENSFAB PTE, LTD., # 01-01, The Cavendish, Singapore (SG)

(21) Appl. No.: 11/665,528

(22) PCT Filed: Oct. 18, 2005
(86) PCT No.: PCT/SG05/00361

§ 371 Date: Dec. 31, 2007

(30) Foreign Application Priority Data
Oct. 18, 2004 (SG) 200407545-3

(51) Int. Cl. H01L 29/00; H01L 21/00

(52) U.S. Cl. 257/416; 438/53; 257/E29.001; 257/E21.001

(57) ABSTRACT

A silicon microphone includes a diaphragm that is able to flex over an aperture, an area allowing electrical connection to the diaphragm, a backplate parallel to and spaced apart from the diaphragm and extending over the aperture, the backplate being fixed, the backplate and diaphragm forming the parallel plates of a capacitor, the backplate and diaphragm being attached to and insulated from each other around at least a portion the boundary of the aperture, and a backplate support attached to the backplate around the boundary of the aperture, the backplate support not forming an electrical connection with the backplate.

### FIELD OF INVENTION

The invention relates to silicon microphones and in particular to silicon microphones with backplate chips.

### BACKGROUND

A capacitive microphone typically includes a diaphragm including an electrode attached to a flexible member and a backplate parallel to the flexible member attached to another electrode. The backplate is relatively rigid and typically includes a plurality of holes to allow air to move between the backplate and the flexible member. The backplate and flexible member form the parallel plates of a capacitor. Acoustic pressure on the diaphragm causes it to deflect which changes the capacitance of the capacitor. The change in capacitance is processed by electronic circuitry to provide an electrical signal that corresponds to the change.

Microelectronic mechanical systems (MEMS), including miniature microphones, are fabricated with techniques commonly used for making integrated circuits. Potential uses for MEMS microphones include microphones for hearing aids and mobile telephones, and pressure sensors for vehicles.

Once a silicon microphone has been fabricated it must be packaged onto a device. During this packaging process the backplate of the silicon microphone may displace or deform. Any movement of the backplate during packaging may reduce the sensitivity of the microphone or prevent operation of the microphone.

### SUMMARY OF INVENTION

It is the object of the present invention to silicon microphone with a reduced risk of backplate deformation during packaging or to at least provide the public with a useful choice.

In broad terms in one aspect the invention comprises a silicon microphone including a diaphragm that is able to flex over an aperture, an area allowing electrical connection to the diaphragm, a backplate parallel to and spaced apart from the diaphragm and extending over the aperture, the backplate being fixed, the backplate and diaphragm forming the parallel plates of a capacitor, the backplate and diaphragm being attached to and insulated from each other around at least a portion of the boundary of the aperture, and a backplate support attached to the backplate around the boundary of the aperture, the backplate support not forming an electrical connection with the backplate.

In one embodiment the backplate support is formed from an insulator. In another embodiment the silicon microphone includes a layer of insulating material between the backplate and the backplate support.

In broad terms the invention comprises a method of manufacturing a silicon microphone including the steps of:
providing a first wafer including a layer of heavily doped silicon, a layer of silicon and an intermediate layer of oxide between the two silicon layers and having a first major surface on one surface of the layer of heavily doped silicon and a second major surface on the layer of silicon,
providing a second wafer of heavily doped silicon having a first major surface and a second major surface,
forming a layer of oxide on at least the first major surface of the first wafer,
forming a layer of oxide on at least the first major surface of the second wafer,
etching a cavity through the oxide layer on the first major surface of the first wafer and into the layer of heavily doped silicon,
bonding the first major surface of the first wafer to the first major surface of the second wafer,
thinning the first wafer at its second major surface,
patterning and etching acoustic holes in the second major surface of the second wafer,
etching the intermediate layer of oxide from the first wafer,
forming a metal layer on the second major surface of the first wafer, and
forming at least one electrode on the heavily doped silicon of the first wafer and at least one electrode on the second wafer.

The step of bonding the backplate support to the second major surface of the second wafer may occur at any stage after the acoustic holes have been formed in the second wafer.

The step of bonding the backplate support to the second major surface of the second wafer may include the step of bonding an insulator including an aperture to the second major surface of the second wafer and bonding the backplate support to the insulator.

### BRIEF DESCRIPTION OF DRAWINGS

The method of fabricating a silicon microphone will be further described by way of example only and without intending to be limiting with reference to the following drawings, wherein:

FIG. 1A is a side view of the first wafer before fabrication;

FIG. 1B is a side view of the second wafer before fabrication;

FIG. 1C is a side view of the third wafer before fabrication;

FIG. 2A is a side view of the first wafer after the deposition or growth of oxide;

FIG. 2B is a side view of the second wafer after the deposition or growth of oxide;

FIG. 2C is a side view of the third wafer after masking;

FIG. 2D is a side view of the third wafer after drilling or etching;

FIG. 3 is a side view of the first wafer after a cavity has been patterned and etched;

FIG. 4 is a side view of the two wafers bonded together;

FIG. 5 is a side view of the two wafers after the oxide layers have been stripped;

FIG. 6 is a side view of the two wafers after thinning the first wafer;

FIG. 7 is a side view of the two wafers after forming metal on the second wafer and forming acoustic holes in the second wafer;

FIG. 8 is a side view of the two wafers after etching oxide from the bond between the two wafers;

FIG. 8A is a side view of the device of FIG. 8 after addition of the third wafer;

FIG. 9 is a side view of the two wafers after forming metal over the heavily doped layer of the first wafer;

FIG. 9A is a side view of the device of FIG. 9 after addition of the third wafer;

FIG. 10 is a side view of the two wafers after electrodes have been formed;

FIG. 10A is a side view of the device of FIG. 10 after the addition of the third wafer;

FIG. 11 is a bottom view of the completed silicon microphone;

FIG. 12 is a side view of a second embodiment of silicon microphone without electrodes;

FIG. 12A is a side view of the device of FIG. 12 after the addition of the third wafer;

FIG. 13 is a side view of the microphone of FIG. 12 with electrodes;

FIG. 13A is a side view of the microphone of FIG. 13 with the addition of the third wafer;

FIG. 14 is a side view of a silicon microphone with corrugations in the diaphragm; and

FIG. 14A is a side view of the silicon microphone of FIG. 14 with the addition of the third wafer.

### DETAILED DESCRIPTION

The silicon microphone and method of forming a silicon microphone will be described with reference to one particular embodiment of silicon microphone. This is not intended to limit the invention.

The method of fabricating a silicon microphone (without the backplate support) is described and claimed in the Applicant's PCT patent application PCT/SG2004/000152 which is incorporated herein by reference.

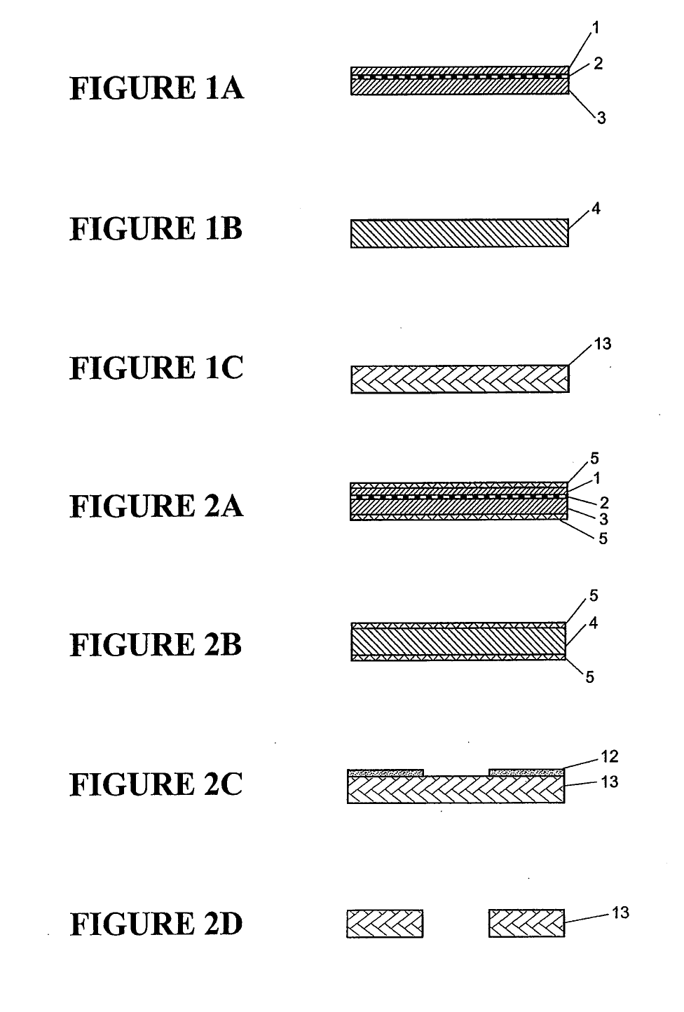

FIG. 1A is a side view of the first wafer used for fabricating a silicon microphone. This wafer is formed from a first layer 1 of highly doped silicon, a middle layer 2 of oxide and the third layer 3 of silicon substrate. In one embodiment the first layer is p⁺⁺ doped silicon and the third layer is an n-type substrate. In an alternative embodiment the first layer may be n⁺⁺ doped silicon and the third layer may be a p-type substrate. Typically the first layer 1 is of the order of 4 microns thick and the second layer is of the order of 2 microns thick. The thickness of these layers used in the silicon microphone will depend on the required characteristics of the microphone. The substrate layer is thicker than the other two layers and for example may be of the order of about 400 to 600 microns thick.

It should be noted that the side views shown are not drawn to scale and are given for illustrative purposes only.

FIG. 1B is a side view of the second wafer used for fabricating a silicon microphone. This wafer comprises a silicon wafer 4. The wafer is heavily doped silicon and may be either p-type or n-type silicon. In a preferred embodiment the wafer is <100> silicon. In other embodiments different silicon surfaces or structures may be used.

FIG. 1C is a side view of a third wafer used to provide backplate support to the silicon microphone. This wafer is preferably Pyrex or borosilicate glass but alternatively can be of any suitable material, either insulating or non-insulating.

Although FIGS. 1A, 1B and 1C are side views of the three wafers, the wafers are three dimensional with two major surfaces. The two major surfaces of the first wafer are the top and bottom surfaces (not shown in FIG. 1A). The first major surface, the top surface, comprises highly doped silicon. The second major surface, the bottom surface, comprises the silicon substrate.

In FIG. 1B the major surfaces are at the top and bottom of the wafer and both comprise the heavily doped silicon wafer.

In FIG. 1C the major surfaces are at the top and bottom of the wafer.

In fabricating the silicon microphone the three wafers are initially processed separately before being bonded together and further processed.

FIGS. 2A and 2B show the first and second wafers after oxide 5 has been formed on the major surfaces of the wafers. Oxide is typically formed on both surfaces of both wafers through thermal growth or a deposition process. Forming oxide on both major surfaces of each wafer reduces the risks of distorting the wafer that would occur if oxide was formed on only one side of each wafer. In an alternative embodiment oxide is formed on only one major surface of each wafer. As can be seen in FIGS. 2A and 2B the thickness of the oxide layers 5 is less than the thickness of the silicon wafer.

It is to be understood that any other suitable dielectric or insulating material, for example silicon nitride, may be used in place of the oxide layer.

The third wafer must include a central aperture so that when fabrication is completed the microphone will operate correctly. If the third wafer is not provided with a central aperture one may be formed in the wafer. FIG. 2C shows the third wafer after patterning and before etching to form a central aperture. The masking layer on the wafer may be a layer of chrome. The aperture can then be formed using concentrated HF to etch into the borosilicate glass. The central aperture can be formed by wet or dry etching. If dry etching is used it may be plasma etching. In alternative embodiments the central aperture may be formed by mechanical means such as ultrasonic drilling.

FIG. 2D is a side view of the third wafer after formation of the aperture in the wafer. The aperture need not extend completely through the wafer but must provide a suitable back volume for the completed silicon microphone. The typical thickness of a back volume may be about 200 microns. After the third wafer is prepared it is cleaned.

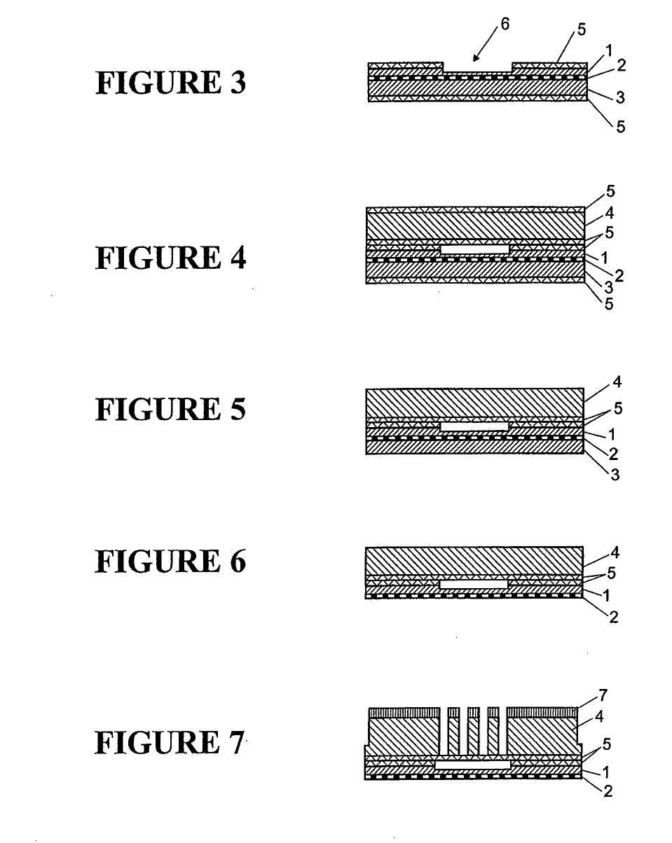

FIG. 3 shows one embodiment in which a cavity 6 is patterned and etched into the first major surface of the first wafer. In this step a portion of the heavily doped silicon layer is etched away to produce a thin section of the heavily doped portion 1. A wet or dry silicon etch may be used. The thickness of the thin section determines properties of the silicon microphone as this section will eventually form the diaphragm of the microphone. In one embodiment a reactive ion etch (RIE) is used to form the cavity. This etch is a time etch so the final thickness of the thin section of the heavily doped portion depends on the etching time.

The desired shape of the cavity is determined from the required properties of the silicon microphone.

In one embodiment a portion of the wafer may be etched from substrate 3 to doped portion 1 to allow an electrode to be formed on doped portion 1 at a later processing stage.

As shown in FIG. 4 the first and second wafers are bonded together. The major surfaces bonded together are the first major surface 1 of the first wafer and one of the major surfaces of the second wafer 4. In a preferred embodiment the two wafers are bonded together using fusion bonding. As shown in FIG. 4 it is the oxide layer 5 of second wafer 4 and the patterned oxide layer 5 of the first wafer that are bonded together.

FIG. 5 shows the first and second wafers after the oxide layers are stripped from the exposed major surfaces of these wafers. Oxide stripping is well known and any suitable technique may be used to strip the oxide from the exposed surfaces.

FIG. 6 shows the first and second wafers after the silicon substrate has been removed from the first wafer. In the preferred embodiment this thinning is performed in a single operation. Any suitable technique may be used to remove the layer of substrate from the first wafer.

After thinning of the first wafer acoustic holes are patterned and etched into the second wafer as shown in FIG. 7. To pattern and etch the acoustic holes the first step is to form a layer of oxide 7 on the outer major surface of the second wafer 4. The oxide is then covered with a layer of resist and the resist is then patterned. Etching is performed to etch the acoustic holes through the oxide 7 and silicon 4. The etching also etches the oxide layer 5 at the bottom of the acoustic holes to provide access between the acoustic holes and the cavity formed in the heavily doped silicon layer 1 of the first wafer.

FIG. 11 shows the perforated silicon layer and the backplate support 13. The advantage of providing a backplate support on the silicon microphone is that it reduces or prevents movement of the backplate when the silicon microphone is packaged thus providing a more robust silicon microphone. The backplate support provides strength to the backplate. The advantages of using a backplate support of insulating material include enabling designs where the backplate 4 and diaphragm are separated which reduces parasitic capacitance. Backplate support 13 also increases the back volume of the silicon microphone formed by the holes in the second wafer. FIG. 11 shows the outline of silicon 4 that forms the acoustic holes. As can be seen in FIG. 11 in this embodiment channels are formed in silicon 4 so that the section of silicon containing the acoustic holes is anchored to the silicon microphone in one corner. Stabilisation of the silicon layer 4 containing the acoustic holes is needed to prevent unwanted movement of the silicon layer 4 within the silicon microphone. This stabilisation is provided by backplate support 13.

The acoustic holes or apertures in the silicon wafer may be circular and set within a rectangle of the silicon wafer with its centre at the centre of the silicon wafer stack but with length and breadth less than that of the wafer stack. The shape and arrangement of the apertures is chosen to provide suitable acoustic performance from the microphone.

As can also be seen in FIG. 7 the cavity in the first wafer is larger than the area defined by the acoustic holes of the second wafer. By providing a bigger cavity 6 for the diaphragm 1 of the first wafer the required accuracy of the position of the acoustic holes is lessened.

As also shown in FIG. 7 during the etching of the acoustic holes a small area or gap around the perimeter of the silicon microphone may also be etched. In the preferred embodiment this etching is performed by a reactive ion etch-lag (RIE-lag). The RIE-lag is a phenomenon by which, in this case, the smaller dimensioned perimeter gap in the resist mask etches to a lesser depth than the larger dimensioned acoustic holes. Because of the RIE-lag, the gap about the perimeter of the silicon microphone does not completely etch through the silicon layer 4. This gap is shown as a step in the side views of FIGS. 7 to 10A. The incompletely etched perimeter provides lines of weakness where the bonded wafer will break when stressed, i.e. when subjected to pressure by a roller. Forming this incomplete etch allows dicing of the wafer, into individual microphone chips, without the use of abrasives or wet processes thereby reducing possible damage to the fragile diaphragm. The partial etch should be sufficiently deep to allow easy breakage of the wafer at dicing but shallow enough to allow easy handling of the wafer without breakage before dicing.

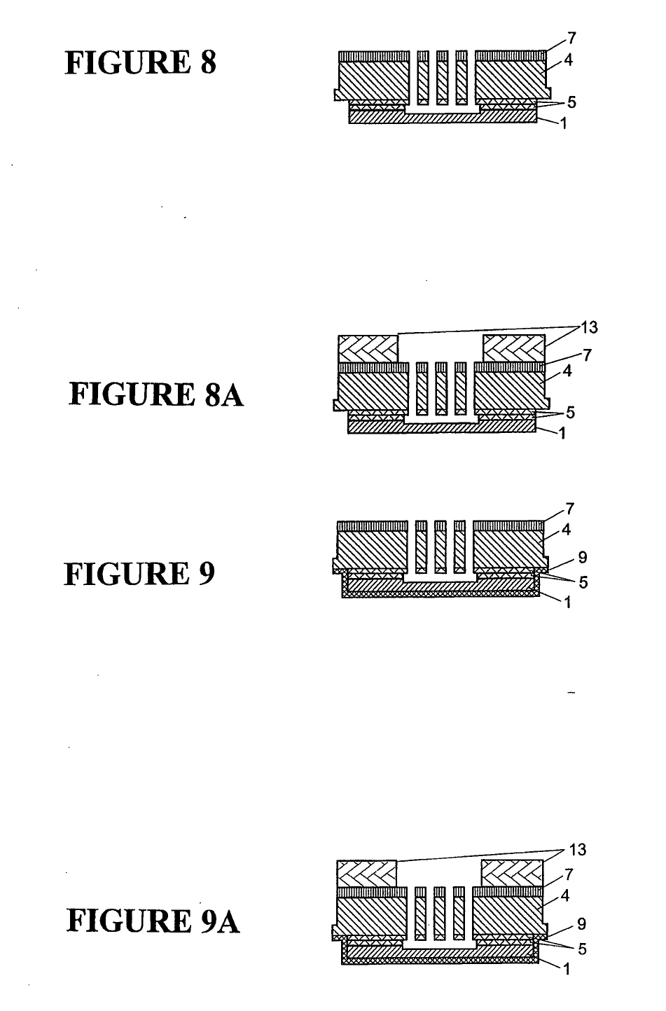

FIG. 8 shows the result of further patterning and etch steps on the bonded wafers. In these steps the oxide layer 2 is patterned to define an isolated area of the heavily doped silicon 1 which is then etched. The oxide layer 2 is then etched away from the heavily doped silicon layer 1. The oxide layers 5 around the isolated area of the diaphragm are etched away to expose portions of the generally inner major face of the second wafer 4. The oxide layer 5 inside the acoustic holes is etched away. In the case of using RIE, the opposite faces of the combined silicon wafer are etched in separate steps. After these etch steps, the remaining portion of the highly doped silicon 1, as defined by the isolated area, is less than the length of the large portion of the silicon 4 of the second wafer (excluding the partially etched silicon at the perimeter of the silicon microphone).

FIG. 8A shows the silicon microphone of FIG. 8 after bonding the third wafer, backplate support 13, to the second major surface of the second wafer. In the preferred embodiment the third wafer is anodically bonded to the second wafer. The third wafer may be bonded to the second wafer at any stage after the acoustic holes have been etched in the second wafer. If the third wafer is of a non-insulating material an insulating layer is bonded to the second wafer and the third wafer is bonded to the insulating layer.

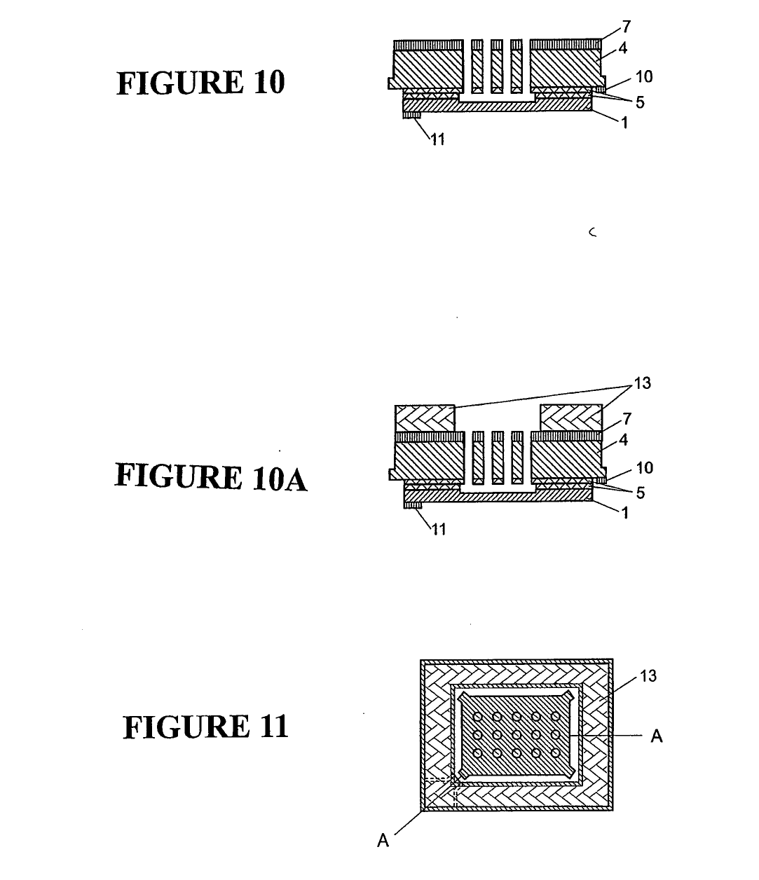

FIG. 9 shows one embodiment with a layer of metal formed over the heavily doped silicon layer of the first wafer and the exposed silicon of the second wafer. As shown in FIG. 9 this metal layer is sputtered globally. The metal is then etched to form at least two electrodes 10, 11 as shown in FIG. 10. At least one electrode 11 is formed on the layer of heavily doped silicon and at least one electrode 10 is formed on the exposed first, inner, major face of the silicon 4 of the second wafer.

In another embodiment the electrodes 10, 11 are formed by using a shadow mask to deposit metal directly in the required pattern.

FIG. 9A shows the silicon microphone of FIG. 9 after bonding the third wafer to the second major surface of the second wafer. In the preferred embodiment the third wafer is anodically bonded to the second wafer. The third wafer may be bonded to the second wafer either before or after the step of forming a layer of metal over the heavily doped silicon layer of the first wafer and the exposed silicon of the second wafer. If the third wafer is of a non-insulating material an insulating layer is bonded to the second wafer and the third wafer is bonded to the insulating layer.

As can be seen in FIG. 10 electrode 11 is in contact with the heavily doped layer of the first wafer 1 and electrode 10 is in contact with the silicon layer 4 of the second wafer. This allows the microphone to be connected to another device by connection bonds made from only one side of the microphone.

FIG. 10A shows the silicon microphone of FIG. 10 after bonding the third wafer to the second major surface of the second wafer. In the preferred embodiment the third wafer is anodically bonded to the second wafer. The third wafer may be bonded to the second wafer before or after forming the electrodes on the first wafer and the exposed silicon of the second wafer. If the third wafer is of a non-insulating material an insulating layer is bonded to the second wafer and the third wafer is bonded to the insulating layer.

Providing two electrodes on one side of the silicon microphone can also assist in probing of the silicon microphone, for example before the microphone is attached to a carrier or other system. Probing of the silicon microphone can be performed by probing needles on one side of the microphone only instead of needles on two sides of the microphone.

In an alternative embodiment the silicon substrate 3 is not thinned after bonding the two wafers together. In this embodiment substrate 3 is selectively thinned around the cavity and any area where an electrode will be formed. An advantage of this embodiment is that the resulting silicon microphone has improved mechanical strength. A further advantage is that when bonding the third wafer to the silicon microphone before the diaphragm etch (etching substrate 3) the wafer this thicker and less fragile than if substrate 3 had previously been etched. In this embodiment the sequence of etching the backplate in substrate 3 and etching the apertures in the silicon wafer is not important.

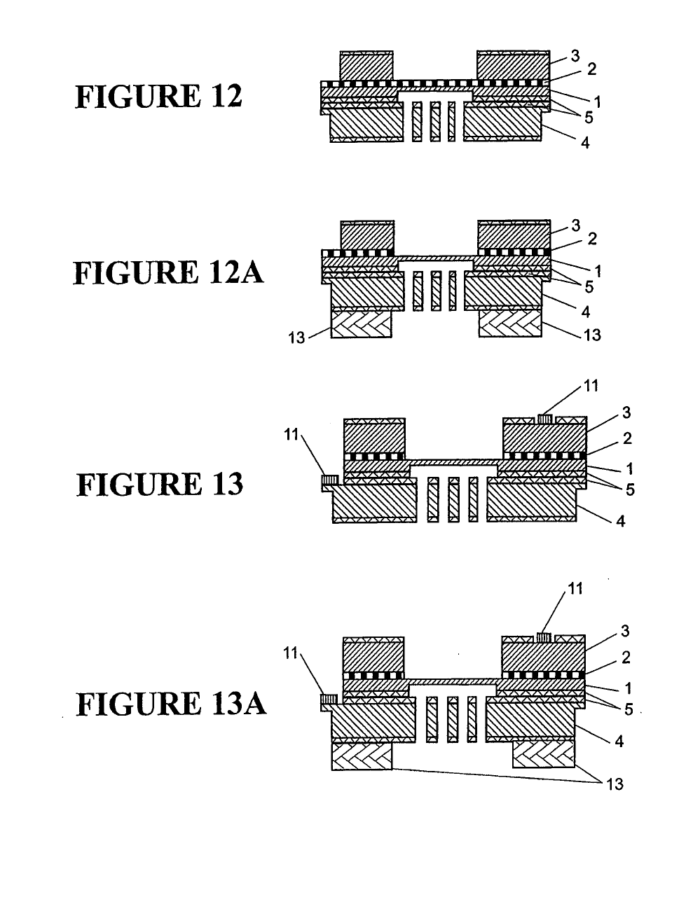

FIG. 12 shows a side view of this silicon microscope after a portion of substrate 3 has been etched to form a position for an electrode. This etching may be performed at the same time that the backplate of the diaphragm is etched in substrate 3. Metal for electrodes may then be deposited on the silicon microphone using a shadow mask after removing oxide from the electrode positions. FIG. 13 shows a final view of the silicon microphone after the electrodes have been formed.

FIG. 12A shows the silicon microphone of FIG. 12 after bonding the third wafer to the second major surface of the second wafer. In the preferred embodiment the third wafer is anodically bonded to the second wafer. The third wafer may be bonded to the second wafer before or after the diaphragm has been etched. If the third wafer is of a non-insulating material an insulating layer is bonded to the second wafer and the third wafer is bonded to the insulating layer.

FIG. 13A shows the silicon microphone of FIG. 13 after bonding the third wafer to the second major surface of the second wafer. In the preferred embodiment the third wafer is anodically bonded to the second wafer. The third wafer may be bonded to the second wafer before or after electrodes have been formed on the first wafer. If the third wafer is of a non-insulating material an insulating layer is bonded to the second wafer and the third wafer is bonded to the insulating layer.

In another alternative embodiment substrate 3 is thinned to oxide layer 2 or to highly doped silicon layer 1 before bonding the wafers together as shown in FIG. 4.

In yet another alternative embodiment substrate 3 is thinned to a predetermined thickness either before or after bonding the wafers together. Substrate 3 can then be selectively patterned and etched.

In yet another alternative embodiment one or both of the wafers may be at the final wafer thickness before processing the wafers.

In any of these embodiments the third wafer can be bonded to the second wafer at any stage after the acoustic holes have been formed in the backplate.

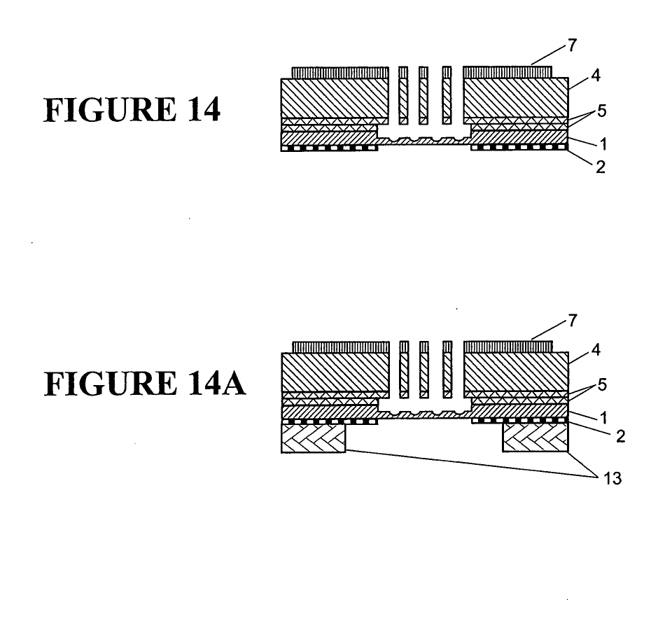

FIG. 14 shows an alternative embodiment of silicon microphone of the invention. In this embodiment the diaphragm of the silicon microphone is over-etched to form a series of corrugation in the diaphragm. An advantage of corrugations is that it improves the strength of the silicon microphone. It should be noted that the silicon microphone of FIG. 14 is not complete and does not show any electrodes. Forming corrugations in the diaphragm can be combined with any other embodiment of silicon microphone of the invention. For example the corrugations may be combined with the microphones of FIG. 11 or 13.

FIG. 14A shows the silicon microphone of FIG. 14 after bonding the third wafer to the second major surface of the second wafer. In the preferred embodiment the third wafer is anodically bonded to the second wafer. The third wafer may be bonded to the second wafer after the corrugations are formed in the diaphragm. If the third wafer is of a non-insulating material an insulating layer is bonded to the second wafer and the third wafer is bonded to the insulating layer.

Embodiments of the invention will be further illustrated by the following example.

### EXAMPLE

Three wafers are provided; the first wafer comprises a 4 micron layer of p⁺⁺ doped silicon, a 2 micron oxide layer, and an n-type substrate; the second wafer comprises p-type silicon; and the third wafer comprises borosilicate glass.

A layer of oxide of about 1 micron is grown on each major surface of the two wafers by thermal growth. The oxide layer is then etched from a portion of the first wafer and an underlying portion of the p⁺⁺ doped silicon layer is also etched to provide a cavity in the p⁺⁺ doped silicon of about 2 microns. The etching is a dry reactive ion etch.

The cavity side of the first wafer is then fusion bonded to an oxide covered surface of the second wafer and the outer oxide layers of each wafer are stripped. The silicon substrate of the first wafer is also stripped using a suitable stripping technique for example lapping, grinding or etching.

A reactive ion etch is performed to etch acoustic holes in the silicon. Reactive ion etch lag causes the etch at the perimeter of the silicon microphone wafer to etch at a slower rate and therefore a lesser depth, as the resist provides a smaller surface area for etching than that of the acoustic holes.

Following this, oxide is etched from the acoustic holes and the outer oxide layer of the first wafer is also etched away. After this step the p⁺⁺ layer of silicon and the layers of oxide between the two wafers are etched around the perimeter of the wafer to expose a portion of the front, now inner, surface of the silicon of the second wafer.

The third wafer is ultrasonically drilled to form an aperture in the wafer. The third wafer is then aligned with the first and second wafers so that the aperture in the third wafer is over the acoustic holes of the second wafer. The third wafer is then anodically bonded to the second wafer.

Metal is then sputtered over the p⁺⁺ layer of silicon and the exposed portions of silicon from the second wafer. The metal is patterned etched to form two electrodes.

The foregoing describes the invention including preferred forms thereof. Alterations and modifications as will be obvious to those skilled in the art are intended to be incorporated in the scope hereof as defined by the accompanying claims.

1. A silicon microphone including
a diaphragm that is able to flex over an aperture,
an area allowing electrical connection to the diaphragm,
a backplate parallel to and spaced apart from the diaphragm and extending over the aperture, the backplate being fixed,
the backplate and diaphragm forming the parallel plates of a capacitor,
the backplate and diaphragm being attached to and insulated from each other around at least a portion of the boundary of the aperture, and
a backplate support attached to the backplate around the boundary of the aperture, the backplate support not forming an electrical connection with the backplate.

2. A silicon microphone as claimed in claim 1 wherein the backplate support is formed from an insulator.

3. A silicon microphone as claimed in claim 1 or claim 2 wherein the silicon microphone includes a layer of insulating material between the backplate and the backplate support.

4. A method of manufacturing a silicon microphone including the steps of:
providing a first wafer including a layer of heavily doped silicon, a layer of silicon and an intermediate layer of oxide between the two silicon layers and having a first major surface on one surface of the layer of heavily doped silicon and a second major surface on the layer of silicon,
providing a second wafer of heavily doped silicon having a first major surface and a second major surface,
forming a layer of oxide on at least the first major surface of the first wafer,
forming a layer of oxide on at least the first major surface of the second wafer,
etching a cavity through the oxide layer on the first major surface of the first wafer and into the layer of heavily doped silicon,
bonding the first major surface of the first wafer to the first major surface of the second wafer,
thinning the first wafer at its second major surface,
patterning and etching acoustic holes in the second major surface of the second wafer,
etching the intermediate layer of oxide from the first wafer,
forming a metal layer on the second major surface of the first wafer, and
forming at least one electrode on the heavily doped silicon of the first wafer and at least one electrode on the second wafer.

5. A method of manufacturing a silicon microphone as claimed in claim 4 wherein the step of bonding a backplate support to the second major surface of the second wafer occurs at any stage after the acoustic holes have been formed in the second wafer.

6. A method of manufacturing a silicon microphone as claimed in claim 4 or claim 5 wherein the step of bonding a backplate support to the second major surface of the second wafer includes the step of bonding an insulator including an aperture to the second major surface of the second wafer and bonding the backplate support to the insulator.
